(19) United States
(12) Patent Application Publication
(10) Pub. No.: US 2025/0324900 A1
(43) Pub. Date: Oct. 16, 2025

(54) RESTRICTED AREA PRINTING BY INK DRAWING (RAPID) FOR SOLUTION-PROCESSED THIN FILMS

(71) Applicant: Arizona Board of Regents on Behalf of the University of Arizona, Tucson, AZ (US)

(72) Inventors: Adam Printz, Tucson, AZ (US); Matthew Dailey, Tucson, AZ (US); Subham Dastidar, Tucson, AZ (US)

(21) Appl. No.: 18/864,847

(22) PCT Filed: May 9, 2023
(86) PCT No.: PCT/US23/66797

§ 371 Date: Nov. 11, 2024

Related U.S. Application Data
(60) Provisional application No. 63/339,909, filed on May 9, 2022.

(51) Int. Cl. H10K 71/18; H01L 21/67; H10K 71/40; H10K 71/80

(52) U.S. Cl. CPC H10K 71/18; H01L 21/6715; H10K 71/40; H10K 71/80; H01L 21/67103

(57) ABSTRACT

The present invention relates to an apparatus for printing, and methods of using to prepare printed articles (such as films suitable for use in electronics applications).

### STATEMENT OF FEDERALLY SPONSORED RESEARCH AND DEVELOPMENT

This invention was made with government support under Grant No. DE-EE0009523 awarded by the U.S. Department of Energy (DOE). The government has certain rights in the invention.

### CROSS REFERENCE TO RELATED APPLICATIONS

This application claims priority to U.S. Application No. 63/339,909, filed on May 9, 2022, the contents of which are hereby incorporated by reference in its entirety.

### FIELD OF THE INVENTION

The field of the invention relates generally to solution-processed electronics and processes for the preparation thereof.

### BACKGROUND

A key advantage of solution-processable electronics is that they are printable at scale, enabling high throughput production of low-cost devices. Most research on these promising materials is performed at the lab scale, typically using spin-coating—a highly controlled but inherently unscalable process—to fabricate thin films. Insight gained from studying spin-coated materials is not directly translatable to more scalable printing processes such as slot-die or gravure printing, doctor blading, and spray-coating. While these processes can result in relatively smooth films with controllable thicknesses, they do not provide fine control over the morphology or crystallization of films, resulting in higher defect densities and poorer performance than films produced in a research setting.

Process control with current scalable printing techniques is limited; while these techniques are efficient at depositing ink onto substrates, they do not include any direct environmental control over the deposited inks at nanometer-to-micron length scales. An approach to addressing this lack of control would be to apply external conditions to the ink itself to direct processes such as nucleation. In many of these printing processes, the substrates are heated to provide control over crystallization rates in the ink; however they do not provide any additional environmental controls.

A printing process in which the environment of the ink is highly controllable is thus of significant interest, both on the production scale, but also for basic sciences research.

### BRIEF DESCRIPTION OF THE DRAWINGS

FIGS. 1A-1C are schematic drawings of an exemplary embodiment of an apparatus according to the invention.

FIGS. 2A-2C are schematic drawings of an exemplary embodiment of an apparatus according to the invention.

FIG. 3 is a perspective drawing of an exemplary embodiment of an apparatus according to the invention.

FIG. 4 is an electron micrographic image of a comparative example of a perovskite material according to the invention.

FIG. 5 is an electron micrographic image of a comparative example of a perovskite material according to the invention.

FIG. 6 is a schematic perspective drawing of an exemplary embodiment of a roll-to-roll printing system according to the invention.

### DETAILED DESCRIPTION

All publications mentioned herein are incorporated by reference to the extent they support the present invention.

### 1.0 Definitions

For the purposes of promoting an understanding of the principles of the invention, reference will now be made to certain embodiments and specific language will be used to describe the same. It will nevertheless be understood that no limitation of the scope of the invention is thereby intended, and alterations and modifications in the illustrated invention, and further applications of the principles of the invention as illustrated therein are herein contemplated as would normally occur to one skilled in the art to which the invention relates.

Unless defined otherwise, all technical and scientific terms used herein have the same meaning as commonly understood by one of ordinary skill in the art to which this invention pertains.

For the purpose of interpreting this specification, the following definitions will apply and whenever appropriate, terms used in the singular will also include the plural and vice versa. In the event that any definition set forth below conflicts with the usage of that word in any other document, including any document incorporated herein by reference, the definition set forth below shall always control for purposes of interpreting this specification and its associated claims unless a contrary meaning is clearly intended (for example in the document where the term is originally used).

The use of “or” means “and/or” unless stated otherwise.

The use of “a” herein means “one or more” unless stated otherwise or where the use of “one or more” is clearly inappropriate.

The use of “comprise,” “comprises,” “comprising,” “include,” “includes,” and “including” are interchangeable and not intended to be limiting. Furthermore, where the description of one or more embodiments uses the term “comprising,” those skilled in the art would understand that, in some specific instances, the embodiment or embodiments can be alternatively described using the language “consisting essentially of” and/or “consisting of.”

As used herein, the terms “about” and “substantially” refer to a ±10% variation from the nominal value. It is to be understood that such a variation is always included in any given value provided herein, whether or not it is specifically referred to.

As used herein, the term “smooth” refers to a surface roughness (Ra) of less than a specified value; for example a root mean square (RMS) value of Ra for a very smooth film surface may be on the order of less than about 10 nm, or less than about 9 nm, or less than about 8 nm, or less than about 7 nm, or less than about 6 nm, or less than about 5 nm, or less than about 4 nm, or less than about 3 nm, or less than about 2 nm, or less than about 1 nm. Surface roughness may be measured using conventional atomic force microscopy (AFM) techniques.

As used herein, the term “ink” refers to a composition comprising one or more solvents and one or more ingredients, for example, chosen from any of chemically reactive precursors, small molecules, polymers, colloidal nanoparticles/microparticles, and other suitable additives. In some embodiments, the composition may comprise a solution, emulsion or suspension. In some embodiments, the ink comprises one or more volatile solvents. In some embodiments the ink comprises a solvent having a boiling point of less than about 200° C. at atmospheric pressure, or less than about 1750° C. at atmospheric pressure, or less than about 150° C. at atmospheric pressure, or less than about 125° C. at atmospheric pressure, or less than about 100° C. at atmospheric pressure. For example, the ink may be a semiconductor ink (i.e., an ink used in the preparation of semiconductors).

As used herein, the term “substrate” refers to a material comprising a flat surface. The substrate may be smooth. In some embodiments, the substrate may have a surface that is substantially smooth. In some embodiments, the substrate may have a surface that has some degree of roughness. In some embodiments, the substrate may be chosen from silicon, glass, metal or plastic. In some embodiments, the substrate may be chosen from thermoplastics, wherein the substrate may be chosen from polyethylene terephthalate or polyethylene naphthalate. In some embodiments, the substrate may be chosen from thermosets, wherein the substrate may be chosen from epoxy resins. In some embodiments, the substrate may be optionally coated with thin layers of a material chosen from metals, oxides, small organic molecules or polymers for electrodes, charge transport layers, or barrier layers.

As used herein, the term “bevel” refers to an edge on a surface, wherein the edge of the surface is sloped at a particular angle. The slope of the bevel may be of any angle except 45° and except 90°. In some embodiments, the angle may be between about 25° to about 65°, or between about 30° to about 60°, or between about 35° to about 55°, or between about 40° to about 50°, or between 42° to about 48°, or between about 44° to about 46°.

As used herein, the term “chamfer” refers to an edge on a surface, wherein the edge of the surface is sloped at a particular angle of 45°.

As used herein, the term “superstrate” refers to a material comprising a smooth flat surface. In some embodiments, the superstrate may comprise a smooth flat surface that is drawing/shearing the ink. The superstrate may be made from materials such as silicon, glass, ceramics, metals, etc. In some embodiments, the superstrate may be made from silicon wafers. In some embodiments, the superstrate may be a resistive heater. In some embodiments, the superstrate may be a glass coated with indium tin oxide (ITO). The superstrate may be relatively flat, comprising a planar superstrate face. In some embodiments, the superstrate is substantially smooth. In some embodiments, the superstrate may have a surface that has some degree of roughness. In some embodiments, the superstrate has roughness at least 1 order of magnitude less than the desired film roughness. The superstrate may be modular. In some embodiments, a superstrate may comprise at least one bevel, wherein the beveled edge is normal to the direction of motion of the superstrate or the substrate. In another embodiment, a superstrate may comprise at least one chamfer, wherein the chamfered edge is normal to the direction of motion of the superstrate or the substrate.

As used herein, the term “ink dispenser” refers to an apparatus that deposits ink onto a surface. The ink dispenser may comprise one or more components to deposit ink onto a surface, e.g., by spraying, dripping, slot-die head, doctor blading, ink bath, or transfer printing.

The term “moving element” is used interchangeably herein to refer to the “substrate assembly”. The term “substrate assembly” as disclosed herein encompasses a moving element.

As used herein, the term “kinematic control” refers to a system of actuators that can control up to 6-axis (pitch, yaw, rotation, and x, y, z). Kinematic control may be achieved using a motorized or manual actuator. In some embodiments, the manual actuator may comprise 3 or more axes.

As used herein, the term “electronic device” refers to any hardware which performs one or more specific functions and operates on any form or combination of energy. In some embodiments, electronic device may refer to a semiconductor, transistor, battery, fuel cell, energy device, or photovoltaic cell.

The following is an illustration of an exemplary embodiment showing how the apparatus disclosed herein may be configured:

Unlike traditional printing methods, the invention provides an apparatus and methods that may give improved control over the thin-film growth process, which may result in films of higher quality. In some embodiments, films of higher quality may comprise improved electronic performance, mechanical stability and/or chemical stability. In some embodiments, the electronic performance may depend on factors such as carrier diffusion length and/or mobility. In some embodiments, the mechanical stability may depend on factors such as fracture energy and/or resilience to repeated thermal and/or bending stresses. In some embodiments, the chemical stability may depend on factors such as compositional resilience to aging at high temperatures and/or moisture.

In some embodiments, films may comprise a solar or photovoltaic film, LED film, or battery film.

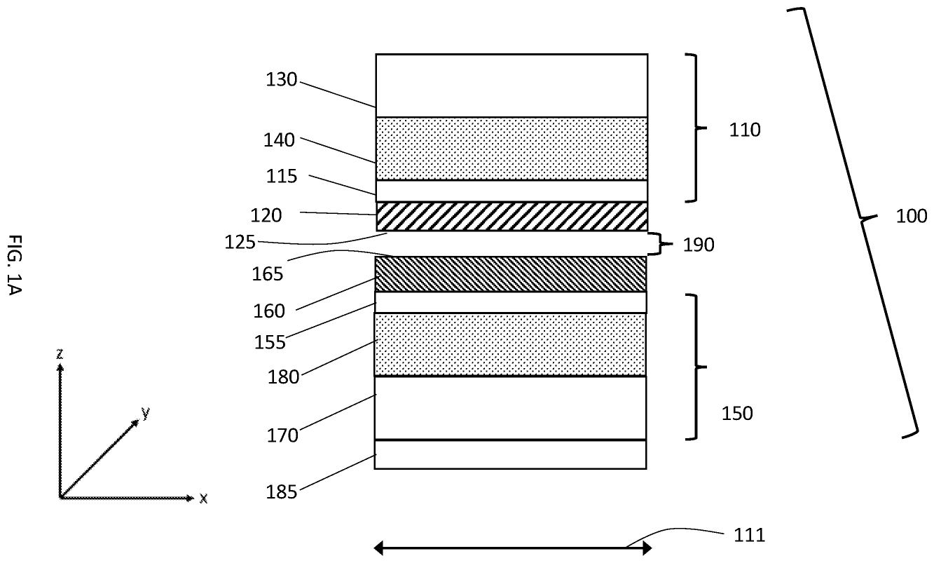

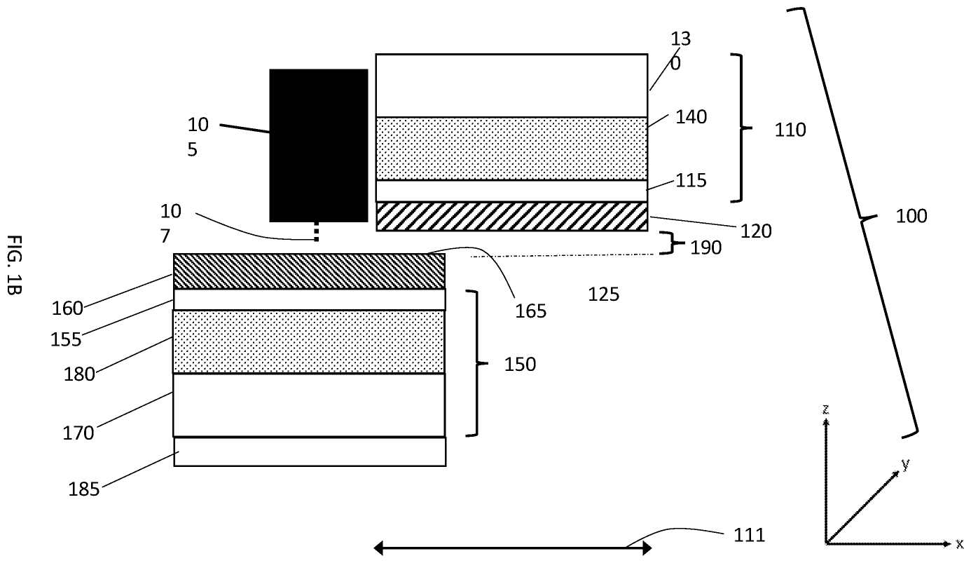

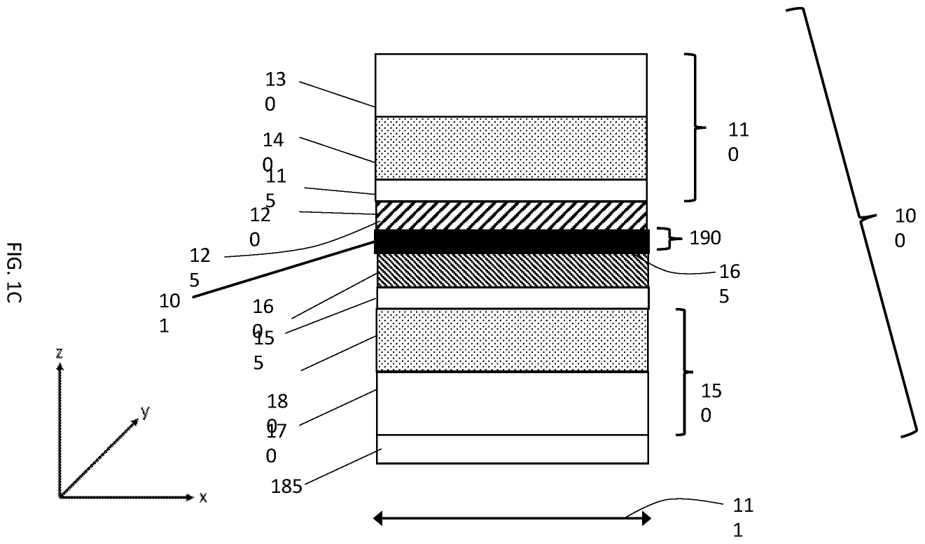

FIG. 1A shows an exemplary embodiment of the invention comprising an apparatus 100. Apparatus 100 comprises a superstrate assembly 110 and a substrate assembly 150. Superstrate assembly 110 and substrate assembly 150 are shown as vertically aligned. In some embodiments, substrate assembly 150 is moveable along a horizontal axis 190 whereas superstrate assembly 110 does not move relative to horizontal axis 190. In some other embodiments, either or both of superstrate assembly 110 and substrate assembly 150 may move along horizontal axis 190, or in any direction in a horizontal xy-plane. In still other embodiments, either or both of superstrate assembly 110 and substrate assembly may rotate independently around orthoganol x-, y-, and z-axes. In some preferred embodiment, superstrate assembly 110 remains static in the horizontal xy-plane, while substrate assembly 150 may move along horizontal axis 111.

Superstrate assembly 110 comprises a superstrate carrier 115 configured to hold a superstrate 120 comprising a substantially planar superstrate face 125. Superstrate assembly 110 further comprises a superstrate positional controller 130 configured to definably convey superstrate carrier 115 from a first position to a second position spaced apart from the first position and to hold superstrate face 125 in a first plane. In a preferred embodiment, the superstrate positional controller 130 is configured to definably conver superstrate carrier 115 from a first position along a vertical z-axis to a second position spaced apart from the first position and to hold superstrate face 125 in a first plane. In some embodiments, superstrate carrier 115 may comprise a clamp, a screw, an adhesive layer, means for applying a vacuum, or other suitable means of attachment. In another embodiment, superstrate carrier 115 may comprise a vacuum plate.

Substrate assembly 150 comprises a substrate carrier 155 configured to receive and hold a substrate 160 comprising a substantially planar substrate face 165. Substrate assembly 150 further comprises a superstrate positional controller 170 configured to definably convey substrate carrier 155 from a third position to a fourth position spaced apart from the first position and to hold substrate face 165 in a second plane substantially parallel to the first plane. In a preferred embodiment, the superstrate positional controller 170 is configured to definably convey substrate carrier 155 from a third position to a fourth position spaced apart from the first position along a vertical z-axis and to hold substrate face 165 in a second plane substantially parallel to the first plane. In some embodiments, substrate carrier 155 may comprise a clamp, a screw, an adhesive layer, or means for applying a vacuum, or other suitable means of attachment. In another embodiment, substrate carrier 155 may comprise a vacuum plate.

In the embodiment shown in FIG. 1A, superstrate positional controller 130 and/or substrate positional controller 170 can position superstrate assembly 110 and substrate assembly 150 so that at least a portion of superstrate assembly 110 and a portion of substrate assembly 150 are superimposed to define a gap between substrate assembly 150 and superstrate assembly 110, and more particularly a gap 190 can be defined by substrate face 165 and superstrate face 125 (when a substrate 160 is held by substrate carrier 155 and a superstrate 120 is held by superstrate carrier 115). In some embodiments, substrate assembly 150 comprises a substrate assembly carriage 185, suitable for transporting substrate assembly 150 in an xy-plane. In some embodiments, substrate assembly carriage 185 may be a conveyer belt, detachably attached to substrate assembly 150.

In some exemplary embodiments of the invention, apparatus 100 comprises at least one component for controlling an environmental parameter of an ink comprises a component 140 for controlling an environmental parameter of ink that may be disposed in gap 190, and substrate assembly 150 comprises a component 170 for controlling an environmental parameter of ink that may be disposed in gap 190. In some other embodiments, apparatus 100 may comprise only component 140 or component 170, while in yet other embodiments, additional such components for controlling an environmental parameter of ink may be present on either or both of superstrate assembly 110 and substrate assembly 150.

In some embodiments, apparatus 100 comprises superstrate 120 detachably attached to superstrate carrier 115. In some embodiments, apparatus 100 comprises substrate 160 detachably attached to substrate carrier 155. In some embodiments, apparatus 100 comprises superstrate 120 detachably attached to superstrate carrier 115 and substrate 160 detachably attached to substrate carrier 155.

Referring now to FIG. 1B, in some exemplary embodiments of the invention apparatus 100 comprises an ink dispenser 105 positioned to dispense an ink 107 onto substrate face 165. Ink dispenser 105 is preferably disposed adjacent to substrate assembly 110. In some embodiments, ink dispenser 105 is attached to superstrate assembly 110. Ink dispenser 105 may include a means for dispensing ink 107 onto substrate face 165, including a means such as a slot-die, a sprayer for spray coating, a doctor blade, or other suitable coating means known to those having skill in the art.

In FIG. 1B, substrate assembly 150 is shown displaced from superstrate assembly 110 along horizontal axis 111 such that substrate face 165 is disposed in a position for ink 107 to be dispensed thereon.

FIG. 1C shows an exemplary embodiment of apparatus 100 with ink layer 101 confined in gap 190, between superstrate face 125 and substrate face 165. Advantageously, ink layer 101 when so confined, may be subjected to control of various environmental parameters, with minimal loss of solvent due to evaporation.

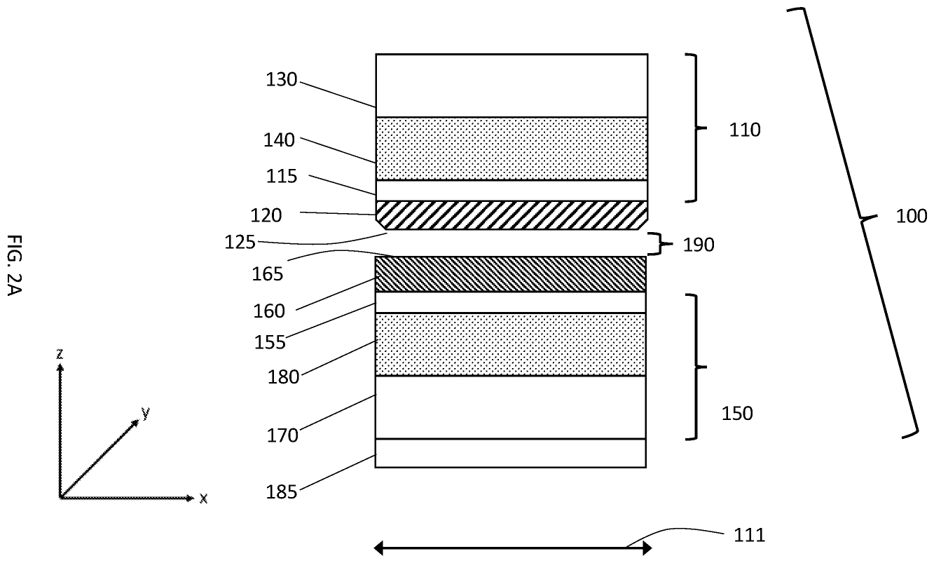

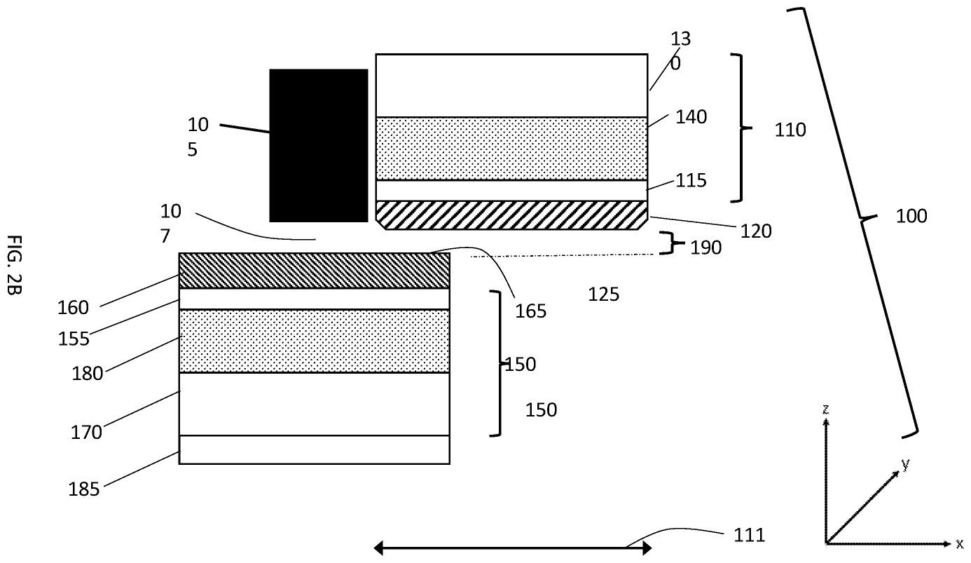

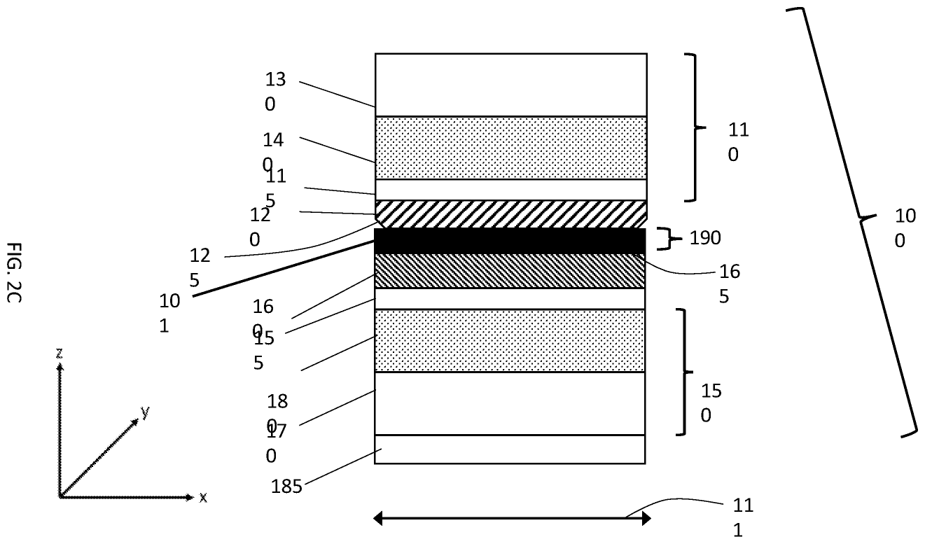

FIG. 2A shows an exemplary embodiment of the invention comprising an apparatus 100. Apparatus 100 comprises a superstrate assembly 110 and a substrate assembly 150. Superstrate assembly 110 and substrate assembly 150 are shown as vertically aligned. In some embodiments, substrate assembly 150 is moveable along a horizontal axis 190 whereas superstrate assembly 110 does not move relative to horizontal axis 190. In some other embodiments, either or both of superstrate assembly 110 and substrate assembly 150 may move along horizontal axis 190, or in any direction in a horizontal xy-plane. In still other embodiments, either or both of superstrate assembly 110 and substrate assembly may rotate independently around orthoganol x-, y-, and z-axes. In some preferred embodiment, superstrate assembly 110 remains static in the horizontal xy-plane, while substrate assembly 150 may move along horizontal axis 111.

Superstrate assembly 110 comprises a superstrate carrier 115 configured to hold a superstrate with bevel (or chamfer) 120 comprising a substantially planar superstrate face 125. Superstrate assembly 110 further comprises a superstrate positional controller 130 configured to definably convey superstrate carrier 115 from a first position to a second position spaced apart from the first position and to hold superstrate face 125 in a first plane. In a preferred embodiment, the superstrate positional controller 130 is configured to definably conver superstrate carrier 115 from a first position along a vertical z-axis to a second position spaced apart from the first position and to hold superstrate face 125 in a first plane. In some embodiments, superstrate carrier 115 may comprise a clamp, a screw, an adhesive layer, means for applying a vacuum, or other suitable means of attachment. In another embodiment, superstrate carrier 115 may comprise a vacuum plate.

Substrate assembly 150 comprises a substrate carrier 155 configured to receive and hold a substrate 160 comprising a substantially planar substrate face 165. Substrate assembly 150 further comprises a superstrate positional controller 170 configured to definably convey substrate carrier 155 from a third position to a fourth position spaced apart from the first position and to hold substrate face 165 in a second plane substantially parallel to the first plane. In a preferred embodiment, the superstrate positional controller 170 is configured to definably convey substrate carrier 155 from a third position to a fourth position spaced apart from the first position along a vertical z-axis and to hold substrate face 165 in a second plane substantially parallel to the first plane. In some embodiments, substrate carrier 155 may comprise a clamp, a screw, an adhesive layer, or means for applying a vacuum, or other suitable means of attachment. In another embodiment, substrate carrier 155 may comprise a vacuum plate.

In the embodiment shown in FIG. 2A, superstrate positional controller 130 and/or substrate positional controller 170 can position superstrate assembly 110 and substrate assembly 150 so that at least a portion of superstrate assembly 110 and a portion of substrate assembly 150 are superimposed to define a gap between substrate assembly 150 and superstrate assembly 110, and more particularly a gap 190 can be defined by substrate face 165 and superstrate face 125 (when a substrate 160 is held by substrate carrier 155 and a superstrate with bevel (or chamfer) 120 is held by superstrate carrier 115). In some embodiments, substrate assembly 150 comprises a substrate assembly carriage 185, suitable for transporting substrate assembly 150 in an xy-plane. In some embodiments, substrate assembly carriage 185 may be a conveyer belt, detachably attached to substrate assembly 150.

In some exemplary embodiments of the invention, apparatus 100 comprises at least one component for controlling an environmental parameter of an ink comprises a component 140 for controlling an environmental parameter of ink that may be disposed in gap 190, and substrate assembly 150 comprises a component 170 for controlling an environmental parameter of ink that may be disposed in gap 190. In some other embodiments, apparatus 100 may comprise only component 140 or component 170, while in yet other embodiments, additional such components for controlling an environmental parameter of ink may be present on either or both of superstrate assembly 110 and substrate assembly 150.

In some embodiments, apparatus 100 comprises superstrate with bevel (or chamfer) 120 detachably attached to superstrate carrier 115. In some embodiments, apparatus 100 comprises substrate 160 detachably attached to substrate carrier 155. In some embodiments, apparatus 100 comprises superstrate with bevel (or chamfer) 120 detachably attached to superstrate carrier 115 and substrate 160 detachably attached to substrate carrier 155.

Referring now to FIG. 2B, in some exemplary embodiments of the invention apparatus 100 comprises an ink dispenser 105 positioned to dispense an ink 107 onto substrate face 165. Ink dispenser 105 is preferably disposed adjacent to substrate assembly 110. In some embodiments, ink dispenser 105 is attached to superstrate assembly 110. Ink dispenser 105 may include a means for dispensing ink 107 onto substrate face 165, including a means such as a slot-die, a sprayer for spray coating, a doctor blade, or other suitable coating means known to those having skill in the art.

In FIG. 2B, substrate assembly 150 is shown displaced from superstrate assembly 110 along horizontal axis 111 such that substrate face 165 is disposed in a position for ink 107 to be dispensed thereon.

FIG. 2C shows an exemplary embodiment of apparatus 100 with ink layer 101 confined in gap 190, between superstrate face 125 and substrate face 165. Advantageously, ink layer 101 when so confined, may be subjected to control of various environmental parameters, with minimal loss of solvent due to evaporation.

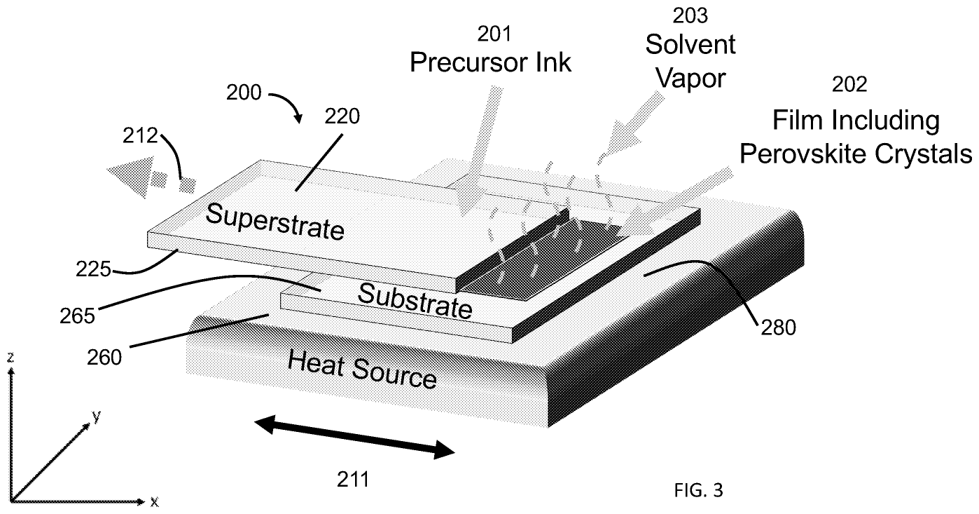

FIG. 3 shows an embodiment of a prototypical apparatus 200 comprising a superstrate 220 comprising a superstrate face 225. Apparatus 200 further comprises a substrate 260 comprising a substrate face 265. Superstrate face 225 is shown oriented towards substrate face 265, such that superstrate face 225 substrate face 265 are substantially parallel, defining a gap therebetween, and at least a portion of superstrate face 225 is superimposed on substrate face 265. An ink 201 is disposed as a layer in the gap defined by superstrate face 225 and substrate face 265. Substrate 260 is disposed on a heat source 280 (serving as a component for controlling an environmental parameter, i.e., heat). FIG. 3 shows apparatus 200 and ink 201 in a condition where heating has been applied to ink 201 from heat source 180 (and through substrate 260), wherein superstrate 220 is displaced in direction 221 to expose the heat-treated ink to atmosphere, with resultant evaporation of solvent as solvent vapor 203 to obtain film 202. In the embodiment shown in FIG. 3, film 202 includes perovskite crystals. Advantageously, an improvement in the size of perovskite crystals may be obtained by such a process, relative to other efforts to obtain perovskite crystals of a useful size for use in, for example, solar power cells or photovoltaic cells.

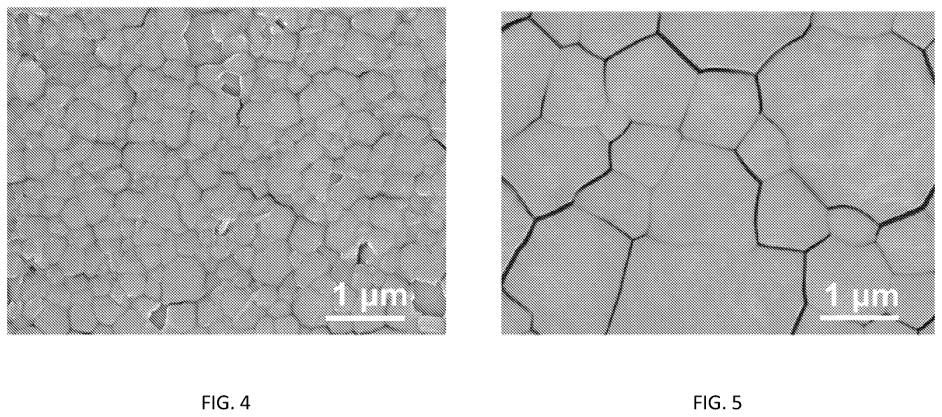

FIG. 4 shows an image of a comparative example of perovskite crystals produced by a conventional means.

FIG. 5 shows an image of an exemplary embodiment of perovskite crystals produced according to methods of the present invention. A comparison of FIG. 4 and FIG. 5 shows an improvement in the size of crystals obtained by an exemplary method of the invention.

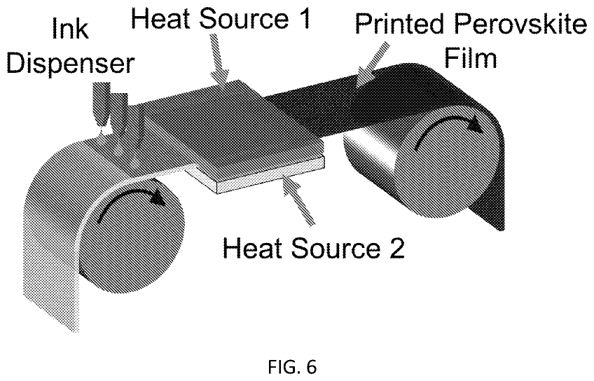

FIG. 6 shows schematic perspective drawing of an embodiment of a roll-to-roll system 500 according to the invention. A substrate is fed over roll 1 past an ink dispenser, where an ink is dispensed onto the substrate to form an ink layer. Subsequently, the substrate and ink layer pass between heat source 1 and heat source 2, to obtain a printed film, which passes over roll 2. In some embodiments, the printed film is a printed perovskite film.

In some embodiments of FIGS. 1 and 2, apparatus 100 is configured with a component to vary printer speed. In some embodiment of FIGS. 1 and 2, apparatus 100 is configured to modify speed of the moving element to vary printer speed.

In an exemplary embodiment of FIGS. 1 and 2, superstrate 120 has substantially planar superstrate face 125, which may or may not be polished, and may be of a material such as silicon (e.g., a silicon wafer), glass, metals, or ceramics. In an exemplary embodiment of FIGS. 1 and 2, superstrate 120 has substantially planar superstrate face 125, which may or may not be polished, and may be of a material such as a silicon wafer. Substrate 160 is what is being printed onto, and has a substantially planar substrate face, and may be of a material such as silicon, glass, or plastic, or any of the previous materials coated with thin layers of other materials including metals, oxides, small organic molecules or polymers (e.g., for electrodes, charge transport layers, or barrier layers). Substrate 160 may have a substantially planar substrate face, and may be of a material including but not limited to thermoplastics such as polyethylene terephthalate, polyethylene napthalate, or thermoset plastics such as epoxy resins. Substrate 160 may have a substantially planar substrate face, and may be of a material such as silicon, glass, or plastic, or any of the previous materials coated with thin layers of other materials including metals, oxides, small organic molecules or polymers for electrodes, charge transport layers, or barrier layers.

Calibration of positions of the substrate and superstrate occurs by leveling the substrate and superstrate using kinematic controls or linear actuators. In another embodiment, both kinematic controls and linear actuators may be manual or motorized. Once calibration is completed to ensure the substantially planar surfaces of the substrate and superstrate are parallel, the superstrate assembly 110 is moved vertically along a z-axis to a position at a distance able to accommodate the thickness of the substrate and ink between it and the moving element. The moving element is controlled by a linear motion controller and in this embodiment moves the substrate in an x-direction away from a position below the superstrate. The moving element may be controlled by a linear actuator. The substrate is then immobilized onto the substrate assembly. The substrate may be immobilized with vacuum, adhesive tape, magnets, screws, or glue. The substrate may be immobilized onto the substrate assembly which may heat or cool the substrate or provide electrical bias.

During operation, the linear motion controller moves the entire moving element with the substrate assembly and immobilized substrate toward the immobilized superstrate assembly (under which it will pass). Just before the substrate passes under the superstrate assembly, ink is deposited onto the substrate. The ink may be deposited onto the substrate by spraying, dripping, slot-die head, doctor blading, ink bath, or transfer printing. To ensure minimal solvent evaporation, the substrate face with the ink is quickly moved under the superstrate face, to confine the ink between the substrate face and superstrate face-which greatly slows down solvent evaporation.

While the ink is in the confined state between the substrate and superstrate, the environment of the ink can be directly controlled by applying heating from the superstrate assembly and/or substrate assembly, applying electrical bias, and having different chemical functionalities on the superstrate or substrate to control the kinetics and/or thermodynamics of crystal nucleation and growth and film formation, all while maintaining its initial concentration because minimal solvent is able to evaporate (only around the edges of the ink, rather than from the top, so the surface area of the ink exposed to the environment is low compared to other processes). The initial concentration may be from about 1 mM to about 10 M, or from 100 mM to about 9 M, or from 200 mM to about 8 M, or from about 300 mM to about 7 M, or from about 400 mM to about 6 M, or from about 500 mM to about 5 M, or from about 600 mM to about 4 M, or from about 700 mM to about 3 M, or from about 800 mM to about 2 M, or from about 900 mM to about 1 M. The moving assembly then moves the substrate assembly such that at least a portion of the substrate face coated with ink is no longer superimposed by the superstrate face, and the solvent in the ink rapidly evaporates, driving film formation from the environmentally controlled ink configuration (i.e., the amount of nuclei/crystals, their size and orientation). Without being bound by theory, it is thought that an observed rapid crystallization occurs during evaporation of the solvent due in part to a supersaturation of the ink.

In some embodiments, the superstrate positional controller may be hydraulic, pneumatic, piezoelectric, electro-mechanical linear actuators, or another suitable controller.

In some embodiments, the substrate positional controller may be hydraulic, pneumatic, piezoelectric, electro-mechanical linear actuators, or another suitable controller.

In some embodiments, the superstrate positional controller and/or the substrate positional controller can position the superstrate face and substrate face so that at least a portion of the superstrate face and at least a portion of the substrate face are superimposed to define a gap. The gap size may be at least about 1 nm to about 1 mm, or 10 nm to about 1 mm between the substrate assembly and the superstrate assembly.

### EMBODIMENTS

Embodiments of the invention are provided, and are not intended to in any way limit the scope of the invention.

Embodiment 1. An apparatus comprising:
a superstrate assembly comprising:
   a superstrate carrier configured to receive and hold a superstrate comprising a planar superstrate face;
   a superstrate positional controller (e.g., hydraulic, pneumatic, piezoelectric, electro-mechanical linear actuators, or other suitable controller) configured to definably convey the superstrate carrier from a first position to a second position spaced apart from the first position and to hold the superstrate face in a first plane;
a substrate assembly comprising:
   a substrate carrier configured to receive and hold a substrate comprising a planar substrate face;
   a substrate positional controller (e.g., hydraulic, pneumatic, piezoelectric, electro-mechanical linear actuators, or other suitable controller) configured to definably convey the substrate carrier from a third position to a fourth position spaced apart from the third position and to hold the substrate face opposite the superstrate carrier in a second plane parallel to the first plane;
   wherein the superstrate positional controller and/or the substrate positional controller can position the superstrate face and substrate face so that at least a portion of the superstrate face and at least a portion of the substrate face are superimposed to define a gap (e.g., with a gap size of from about, at least about 1 nm, about 1 nm to about 1 mm, 10 nm to about 1 mm, etc.) between the substrate assembly and the superstrate assembly; and at least one component for controlling an environmental parameter (e.g., via application of
any of temperature (heating and/or cooling), a magnetic field, an electromagnetic field, a voltage, mechanical interactions (such a vibration, pressure, etc.), sonication, surface chemistry, or combinations of thereof) of an ink disposed in said gap. The superstrate may comprise at least one bevel. In some embodiments, the beveled edge is normal to the direction of motion of the superstrate or the substrate. In another embodiment, a superstrate may comprise at least one chamfer. In some embodiments, the chamfered edge is normal to the direction of motion of the superstrate or the substrate.

Embodiment 2. The apparatus of embodiment 1, wherein said apparatus further comprises a superstrate detachably attached to the superstrate carrier.

Embodiment 3. The apparatus of embodiment 1, wherein said superstrate is a smooth surface (e.g., surface can be chemically inert, or may be chemical “active”, e.g., a surface of the superstrate is functionalized to be reactive with ink disposed in said gap defined in embodiment 1).

Embodiment 4. The apparatus of embodiment 1, wherein said superstrate is a rough surface (e.g., surface can be chemically inert, or may be chemical “active”, e.g., a surface of the superstrate is functionalized (e.g., via addition of a film, etc.) to be reactive with ink disposed in said gap defined in embodiment 1).

Embodiment 5. The apparatus of embodiment 1, wherein said apparatus comprises a component to vary the printer speed (e.g., by modifying the speed of the moving element).

Embodiment 6. The apparatus of embodiment 2, wherein said superstrate is chosen from silicon, glass, ceramics, and metals.

Embodiment 7. The apparatus of embodiment 4, wherein the superstrate surface has a surface roughness average (Ra) in a range of from about 1 nm to about 10 microns. In some embodiments, surface rougnhess of the superstrate surface may be about 10-fold less than the surface roughness of an embodiments of a film article of the invention.

Embodiment 8. The apparatus of embodiment 2, further comprising a leveling edge (e.g., slot-die or spray coating), wherein the superstrate comprises the leveling edge. Embodiment 9. The apparatus of embodiment 1 or embodiment 2, further wherein said apparatus further comprises an ink dispenser attached to the superstrate assembly or the substrate assembly.

Embodiment 10. The apparatus of any one of the preceding embodiments, further comprising a substrate detachably attached to the substrate carrier.

Embodiment 11. The apparatus of embodiment 10, wherein the substrate is chosen from silicon, glass, or plastic (e.g., thermoplastics (such as polyethylene terephthalate or polyethylene naphthalate) or thermosets (e.g., epoxy resins)), optionally coated with thin layers of a material chosen from metals, oxides, small organic molecules or polymers for electrodes, charge transport layers, or barrier layers.

Embodiment 12. The apparatus of embodiment 5, further comprising an ink layer extending from the at least a portion of the superstrate and the at least a portion of the substrate.

Embodiment 13. The apparatus of embodiment 12, wherein the ink layer comprises a semiconductor.

Embodiment 14. The apparatus of any one of the preceding embodiments, wherein said apparatus further comprises a component for depositing ink (for example, an ink dispenser).

Embodiment 15. The apparatus of embodiment 14, wherein said component for depositing ink is configured to deposit ink onto a substrate by spraying, dripping, slot-die head, doctor blading, ink bath, or transfer printing.

Embodiment 16. The apparatus of any one of the preceding embodiments, wherein the substrate carrier is adapted to move along a third plane defined by an x-axis and a y-axis that is perpendicular to the x-axis and wherein the third plane is parallel to the second plane.

Embodiment 17. The apparatus of any one of the preceding embodiments, wherein the superstrate carrier is adapted to move along a z-axis that extends orthogonal to the third plane.

Embodiment 18. The apparatus of any one of the preceding embodiments, wherein component for controlling an environmental parameter controls an environmental parameter selected from the group consisting of temperature, magnetic field, electromagnetic field, voltage, mechanical vibration, applied pressure, sonication, surface chemistry, or combinations thereof.

Embodiment 19. The apparatus of any one of the preceding embodiments, wherein the at least one component for controlling the environmental parameter comprises a temperature control component (e.g., for heating or cooling).

Embodiment 20. The apparatus of embodiment 19, wherein the substrate assembly comprises a first temperature control component, wherein the first temperature control component is disposed proximate the substrate carrier.

Embodiment 21. The apparatus of embodiment 19 or embodiment 20, wherein the superstrate assembly comprises a second temperature control component, wherein the second temperature control component is disposed proximate the substrate carrier.

Embodiment 22. The apparatus of any one of the preceding embodiments, wherein the at least one component for controlling the environmental parameter comprises an electrically-conducting element (e.g., a wire) in selective communication with a source of electricity to apply a voltage between the superstrate and the substrate (may be alternating current (AC) or direct current (DC)).

Embodiment 23. The apparatus of embodiment 22, wherein the electrically-conducting element is integrated with the superstrate.

Embodiment 24. The apparatus of any one of the preceding embodiments, wherein said superstrate carrier further comprises one or more components that provide kinematic control and/or motion control (in x- and/or y- and/or z-direction(s)) of the superstrate carrier (e.g., a system of actuators-actuators that can control up to 6-axis (pitch, yaw, rotation, and x, y, z). Can be motorized or manual. Some examples of linear actuators may include hydraulic-, pneumatic-, piezoelectric-, electro-mechanical-linear actuators, or combinations of these).

Embodiment 25. The apparatus of any one of the preceding embodiments, wherein said substrate carrier further comprises one or more components that provide kinematic control and/or motion control of the substrate carrier (in x- and/or y- and/or z-direction(s)) of the substrate carrier (e.g., a system of actuators-actuators that can control up to 6-axis (pitch, yaw, rotation, and x, y, z). Can be motorized or manual. Some examples of linear actuators may include hydraulic-, pneumatic-, piezoelectric-, electro-mechanical-linear actuators, or combinations of these).

Embodiment 26. An apparatus comprising:
a superstrate assembly comprising:
   a superstrate carrier comprising a superstrate comprising a planar superstrate face;
   a superstrate positional controller configured to definably convey the superstrate carrier from a first position to a second position spaced apart from the first position and to hold the superstrate face in a first plane; and
   optionally, a temperature control component (e.g., a suitable heating component or a cooling component);
a substrate assembly comprising:
   a substrate carrier configured to receive and hold a substrate comprising a planar substrate face;
   a substrate positional controller configured to definably convey the substrate carrier from a third position to a fourth position spaced apart from the third position and to hold the substrate face opposite the superstrate carrier in a second plane parallel to the first plane; and
   optionally, a temperature control component (e.g., a suitable heating component or a cooling component).
wherein the superstrate positional controller and/or the substrate positional controller can position the superstrate assembly and substrate assembly so that at least a portion of the superstrate assembly and a portion of the substrate assembly are superimposed to define a gap between the substrate assembly and the superstrate assembly (e.g., a gap in a range of from abut 10 nm to about 10 mm); and
at least one component for controlling an environmental parameter of an ink disposed in said gap.

Embodiment 27. A method of making an article (e.g., a laminate or film), said method comprising using an apparatus of embodiment 1 to control an environmental parameter of ink while said ink is confined between a superstrate a substrate, to obtain said article.

Embodiment 28. A method of making an article (e.g., a laminate or film), said method comprising
depositing ink onto a substrate;
bringing the deposited ink in contact with the surface of a superstrate;
controlling an environmental parameter said ink while said deposited ink is ink disposed between the superstrate and substrate, to obtain said article.

Embodiment 29. A method of making an article (e.g., a laminate or film), said method comprising
using an apparatus of embodiment 1 to deposit ink onto a substrate;
bringing the deposited ink in contact with the surface of a superstrate;
controlling an environmental parameter said ink while said deposited ink is disposed between the superstrate and substrate,
to obtain said article.

Embodiment 30. A method of making an article (e.g., a laminate or film), said method comprising:
a) depositing ink onto a first planar surface (i.e., substrate);
b) bringing the deposited ink into direct contact with a second planar surface (i.e., superstrate);
c) controlling an environmental parameter of the deposited ink during while said deposited ink is disposed between the first planar surface and the second first planar surface to obtain said article;
wherein the first planar surface defines a first plane;
wherein the second planar surface defines a second plane;
wherein, after the bringing the ink into direct contact with the second planar surface, the first plane is parallel to the second plane.

Embodiment 31. The method any one of embodiments 27 to 30, further comprising separating article from the second planar surface (i.e. substrate).

Embodiment 32. The method of any one of embodiments 27 to 31, wherein the planar surface of the substrate is parallel to the planar surface of the superstrate.

Embodiment 33. The method of any one of embodiments 27 to 32, wherein when the deposited ink is disposed between the first planar surface (i.e., substrate) and the second planar surface (superstate) the evaporative loss of solvent from the deposited ink along the perimeter of said planar surface is less than 1%.

Embodiment 34. The method of any one of embodiments 27 to 33, wherein the environment parameter of said deposited ink is controlled is any of temperature (heating and/or cooling), magnetic field, electromagnetic field, voltage, mechanical interactions (such a vibration, pressure, etc.), sonication, or surface chemistry, or combinations thereof.

Embodiment 35. The method of any one of embodiments 27 to 34, wherein the one or more environmental controls is transmitted via a substrate assembly in an apparatus of embodiment 1.

Embodiment 36. The method of any one of embodiments 27 to 35, wherein the one or more environmental controls is transmitted via a superstrate assembly in an apparatus of embodiment 1.

Embodiment 37. The method of any one of embodiments 27 to 36, wherein the deposited ink comprises a metal halide.

Embodiment 38. A film prepared according to the method of any one of embodiments 27 to 37.

Embodiment 39. The film of embodiment 38, wherein the layer of ink has a thickness of at least 1 nm

Embodiment 40. The film of embodiment 38, wherein the layer of ink has a thickness of at least 10 nm.

Embodiment 41. The film of embodiment 38, wherein the layer of ink has a thickness in a range of from about 10 nm to about 1 mm.

Embodiment 42. The article of any one of embodiments 38 to 41, wherein the article is a perovskite.

Embodiment 43. An electronic device (e.g., semiconductor) comprising an article (e.g., film or laminate) prepared according to the method of any one of embodiments 27 to 37.

Embodiment 44. A method of preparing a film, said method comprising:
a) depositing ink on the surface of a substrate disposed on a substrate assembly of an apparatus according to embodiment 1;
b) modifying one or more parameters of said ink using said component for controlling an environmental parameter of an ink while said ink is disposed in said gap between the substrate assembly and the superstrate assembly.

Embodiment 45. A film prepared according to the method of embodiment 44.

We claim:

1. An apparatus comprising:
a superstrate assembly comprising:
a superstrate carrier configured to receive and hold a superstrate comprising a planar superstrate face;
a superstrate positional controller configured to definably convey the superstrate carrier from a first position to a second position spaced apart from the first position and to hold the superstrate face in a first plane;
a substrate assembly comprising:
a substrate carrier configured to receive and hold a substrate comprising a planar substrate face;
a substrate positional controller configured to definably convey the substrate carrier from a third position to a fourth position spaced apart from the third position and to hold the substrate face opposite the superstrate carrier in a second plane parallel to the first plane;
wherein the superstrate positional controller and/or the substrate positional controller can position the superstrate face and substrate face so that at least a portion of the superstrate face and at least a portion of the substrate face are superimposed to define a gap between the substrate assembly and the superstrate assembly; and
at least one component for controlling an environmental parameter of an ink disposed in said gap.

2. The apparatus of claim 1, wherein said apparatus further comprises a superstrate detachably attached to the superstrate carrier.

3. The apparatus of claim 1, wherein said superstrate is a smooth surface.

4. The apparatus of claim 1, wherein said superstrate is a rough surface.

5. The apparatus of claim 1, wherein said apparatus comprises a component to vary the printer speed.

6. The apparatus of claim 2, wherein said superstrate is chosen from silicon, glass, ceramics, and metals.

7. The apparatus of claim 4, wherein the superstrate surface has a surface roughness average (Ra) in a range of from about 1 nm to about 10 microns.

8. The apparatus of claim 2, further comprising a leveling edge, wherein the superstrate comprises the leveling edge.

9. The apparatus of claim 1 or claim 2, further wherein said apparatus further comprises an ink dispenser attached to the superstrate assembly or the substrate assembly.

10. The apparatus of any one of the preceding claims, further comprising a substrate detachably attached to the substrate carrier.

11. The apparatus of claim 10, wherein the substrate is chosen from silicon, glass, or plastic, optionally coated with thin layers of a material chosen from metals, oxides, small organic molecules or polymers for electrodes, charge transport layers, or barrier layers.

12. The apparatus of claim 5, further comprising an ink layer extending from the at least a portion of the superstrate and the at least a portion of the substrate.

13. The apparatus of claim 12, wherein the ink layer comprises a semiconductor.

14. The apparatus of any one of the preceding claims, wherein said apparatus further comprises a component for depositing ink.

15. The apparatus of claim 14, wherein said component for depositing ink is configured to deposit ink onto a substrate by spraying, dripping, slot-die head, doctor blading, ink bath, or transfer printing.

16. The apparatus of any one of the preceding claims, wherein the substrate carrier is adapted to move along a third plane defined by an x-axis and a y-axis that is perpendicular to the x-axis and wherein the third plane is parallel to the second plane.

17. The apparatus of any one of the preceding claims, wherein the superstrate carrier is adapted to move along a z-axis that extends orthogonal to the third plane.

18. The apparatus of any one of the preceding claims, wherein component for controlling an environmental parameter controls an environmental parameter selected from the group consisting of temperature, magnetic field, electromagnetic field, voltage, mechanical vibration, applied pressure, sonication, surface chemistry, or combinations thereof.

19. The apparatus of any one of the preceding claims, wherein the at least one component for controlling the environmental parameter comprises a temperature control component.

20. The apparatus of claim 19, wherein the substrate assembly comprises a first temperature control component, wherein the first temperature control component is disposed proximate the substrate carrier.

21. The apparatus of claim 19 or claim 20, wherein the superstrate assembly comprises a second temperature control component, wherein the second temperature control component is disposed proximate the substrate carrier.

22. The apparatus of any one of the preceding claims, wherein the at least one component for controlling the environmental parameter comprises an electrically-conducting element in selective communication with a source of electricity to apply a voltage between the superstrate and the substrate.

23. The apparatus of claim 22, wherein the electrically-conducting element is integrated with the superstrate.

24. The apparatus of any one of the preceding claims, wherein said superstrate carrier further comprises one or more components that provide kinematic control and/or motion control.

25. The apparatus of any one of the preceding claims, wherein said substrate carrier further comprises one or more components that provide kinematic control and/or motion control of the substrate carrier.

26. An apparatus comprising:
a superstrate assembly comprising:
a superstrate carrier comprising a superstrate comprising a planar superstrate face;
a superstrate positional controller configured to definably convey the superstrate carrier from a first position to a second position spaced apart from the first position and to hold the superstrate face in a first plane; and
optionally, a temperature control component;
a substrate assembly comprising:
a substrate carrier configured to receive and hold a substrate comprising a planar substrate face;
a substrate positional controller configured to definably convey the substrate carrier from a third position to a fourth position spaced apart from the third position and to hold the substrate face opposite the superstrate carrier in a second plane parallel to the first plane; and
optionally, a temperature control component.
wherein the superstrate positional controller and/or the substrate positional controller can position the superstrate assembly and substrate assembly so that at least a portion of the superstrate assembly and a portion of the substrate assembly are superimposed to define a gap between the substrate assembly and the superstrate assembly; and
at least one component for controlling an environmental parameter of an ink disposed in said gap.

27. A method of making an article, said method comprising using an apparatus of claim 1 to control an environmental parameter of ink while said ink is confined between a superstrate a substrate, to obtain said article.

28. A method of making an article, said method comprising depositing ink onto a substrate;
bringing the deposited ink in contact with the surface of a superstrate;
controlling an environmental parameter said ink while said deposited ink is ink disposed between the superstrate and substrate, to obtain said article.

29. A method of making an article, said method comprising using an apparatus of claim 1 to deposit ink onto a substrate;
bringing the deposited ink in contact with the surface of a superstrate;
controlling an environmental parameter said ink while said deposited ink is disposed between the superstrate and substrate,
to obtain said article.

30. A method of making an article, said method comprising:
a) depositing ink onto a first planar surface;
b) bringing the deposited ink into direct contact with a second planar surface (i.e., superstrate);
c) controlling an environmental parameter of the deposited ink during while said deposited ink is disposed between the first planar surface and the second first planar surface to obtain said article;
wherein the first planar surface defines a first plane;
wherein the second planar surface defines a second plane;
wherein, after the bringing the ink into direct contact with the second planar surface, the first plane is parallel to the second plane.

31. The method any one of claims 27 to 30, further comprising separating article from the second planar surface (i.e. substrate).

32. The method of any one of claims 27 to 31, wherein the planar surface of the substrate is parallel to the planar surface of the superstrate.

33. The method of any one of claims 27 to 32, wherein when the deposited ink is disposed between the first planar surface (i.e., substrate) and the second planar surface (superstate) the evaporative loss of solvent from the deposited ink along the perimeter of said planar surface is less than 1%.

34. The method of any one of claims 27 to 33, wherein the environment parameter of said deposited ink is controlled is any of temperature, magnetic field, electromagnetic field, voltage, mechanical interactions, sonication, or surface chemistry, or combinations thereof.

35. The method of any one of claims 27 to 34, wherein the one or more environmental controls is transmitted via a substrate assembly in an apparatus of claim 1.

36. The method of any one of claims 27 to 35, wherein the one or more environmental controls is transmitted via a superstrate assembly in an apparatus of claim 1.

37. The method of any one of claims 27 to 36, wherein the deposited ink comprises a metal halide.

38. A film prepared according to the method of any one of claims 27 to 37.

39. The film of claim 38, wherein the layer of ink has a thickness of at least 1 nm

40. The film of claim 38, wherein the layer of ink has a thickness of at least 10 nm.

41. The film of claim 38, wherein the layer of ink has a thickness in a range of from about 10 nm to about 1 mm.

42. The article of any one of claims 38 to 41, wherein the article is a perovskite.

43. An electronic device (e.g., a semiconductor) comprising an article (e.g., film or laminate) prepared according to the method of any one of claims 27 to 37.

44. A method of preparing a film, said method comprising:
a) depositing ink on the surface of a substrate disposed on a substrate assembly of an apparatus according to claim 1;
b) modifying one or more parameters of said ink using said component for controlling an environmental parameter of an ink while said ink is disposed in said gap between the substrate assembly and the superstrate assembly.

45. A film prepared according to the method of claim 44.

46. The apparatus of claim 1, wherein said apparatus is an apparatus of FIG. 2A.
